(19) United States
(12) Patent Application Publication
(10) Pub. No.: US 2023/0098595 A1
(43) Pub. Date: Mar. 30, 2023

(54) GENERATING VECTOR VERSIONS OF STRUCTURAL PLANS

(71) Applicant: Unearthed Land Technologies, LLC, Cocoa, FL (US)

(72) Inventors: Charles C. Carrington, Cocoa, FL (US); Aaron Westre, Minneapolis, MN (US)

(21) Appl. No.: 17/487,838

(22) Filed: Sep. 28, 2021

(51) Int. Cl. G06F 30/13; G06K 9/00; G06N 20/20; G06K 9/62

(52) U.S. Cl. CPC G06F 30/13; G06K 9/00463; G06N 20/20; G06K 9/628

(57) ABSTRACT

Methods and systems for improved generation of vector versions of plans for structures are provided. In one embodiment, a method is provided that includes receiving a document that depicts a sheet of a blueprint of a structure. A first machine learning model may be used to identify a portion of the document that contains a plan of the structure. A second machine learning model may be used to determine a type of the plan depicted. A third machine learning model may be used to determine, based on the contents of the portion of the documents locations and labels for individual elements within the plan. A vector version of the floor plan may be generated based on the locations and labels.

### BACKGROUND

Blueprints are available for many buildings and may be used to better understand the layout of the buildings. For example, scanned copies for the blueprints of many buildings are publicly available. Such blueprints may include indications of various features of the building, including floor plans, plumbing arrangements, security system arrangements, electrical connections, and other fixtures within the buildings.

### SUMMARY

The present disclosure presents new and innovative systems and methods for extracting and generating vector versions of plans for structures. In a first aspect, a method is provided that includes receiving a document depicting a sheet of a blueprint of a structure. A first machine learning model may be used to identify a portion of the document that contains a plan of the structure. A second machine learning model may be used to determine a type for the plan depicted within the portion of the document. A third machine learning model may be used to determine, based on the contents of the portion of the document, (i) locations of individual elements within the plan and (ii) labels for the individual elements within the plan. A vector version of the floor plan may be generated based on the locations and labels for individual elements within the floor plan.

In a second aspect according to the first aspect, the first machine learning model identifies a bounding box that surrounds the portion of the document that contains the plan of the building.

In a third aspect according to any of the first and second aspects, the portion of the document is extracted from the document and provided to the second machine learning model.

In a fourth aspect according to any of the first through third aspects, the type is selected from among a predefined plurality of types of plans.

In a fifth aspect according to the fourth aspect, the plurality of types of floor plans includes at least one of a structural plan, an electrical plan, a plumbing plan, an HVAC plan, a life and safety plan, and/or a fire suppression plan.

In a sixth aspect according to any of the first through fifth aspects, locations and labels for individual elements are determined responsive to determining that the type for the floor plan is a structural plan.

In a seventh aspect according to any of the first through sixth aspects, generating the vector version of the floor plan includes, for each element of at least a subset of the individual elements, generating a vector version of the element based on a label corresponding to the element and contents of the floor plan at a location associated with the element, scaling the vector version of the element based on the location associated with the element, and placing the vector version of the element within the vector version of the floor plan based on the location associated with the element.

In an eighth aspect according to any of the first through seventh aspects, receiving the document includes receiving multiple documents depicting multiple sheets of the blueprint of the structure. The method may be repeated at least in part for multiple floor plans depicted in each of at least a subset of the multiple documents.

In a ninth aspect according to the eighth aspect, the method further comprises combining multiple vector versions of the multiple floor plans to generate a three-dimensional representation of the structure.

In a tenth aspect according to the ninth aspect, the method further comprises, prior to determining the locations and labels for individual elements, identifying a common match line within two or more of the multiple documents and combining the two or more of the multiple documents to generate a single floor plan. The single floor plan may be provided to the third machine learning model for use in determining the locations and labels for individual elements.

In an eleventh aspect according to any of the first through tenth aspects, the first model is an object recognition model, the second model is a classifier model, and/or the third model is a segmentation model.

In a twelfth aspect according to any of the first through eleventh aspects, the structure includes at least one of, a building, a vehicle, an infrastructure component, a ship, a spacecraft, an aircraft, a tank, and/or an appliance.

In a thirteenth aspect according to any of the first through twelfth aspects, the structure includes components for one or more of a vehicle, a ship, a spacecraft, an aircraft, a tank, an artillery, and/or a weapon.

In a fourteenth aspect according to any of the first through thirteenth aspects, the floor plan includes an exterior portion surrounding the structure and the vector version of the floor plan includes a representation of the exterior portion.

In a fifteenth aspect according to any of the first through fourteenth aspects, the vector version of the floor plan is at least one of (i) a two-dimensional vector representation of the floor plan and (ii) a three-dimensional vector representation of the floor plan.

In a sixteenth aspect according to any of the first through fifteenth aspects, the vector version of the floor plan allows a user to navigate a three-dimensional representation of the floor plan.

In a seventeenth aspect, a system is provided that includes a processor and a memory. The memory may store instructions which, when executed by the processor, cause the processor to receive a document depicting a sheet of a blueprint of a structure and identify, with a first machine learning model, a portion of the document that contains a plan of the structure. The instructions may also cause the processor to determine, with a second machine learning model, a type for the plan depicted within the portion of the document and determine, with a third machine learning model and based on the contents of the portion of the document, (i) locations of individual elements within the plan and (ii) labels for the individual elements within the floor plan. The instructions may further cause the processor to generate a vector version of the floor plan based on the locations and labels for individual elements within the floor plan.

In an eighteenth aspect according to the seventeenth aspect, the memory contains additional instructions which, when executed by the processor while generating the vector version of the floor plan, causes the processor to, for each element of at least a subset of the individual elements generate a vector version of the element based on a label corresponding to the element and contents of the floor plan at a location associated with the element, scale the vector version of the element based on the location associated with the element, and place the vector version of the element within the vector version of the floor plan based on the location associated with the element.

In a nineteenth aspect according to any of the seventeenth and eighteenth aspects, the first model is an object recognition model, the second model is a classifier model, and/or the third model is a segmentation model.

In a twentieth aspect according to any of the seventeenth through nineteenth aspects, the first machine learning model identifies a bounding box that surrounds the portion of the document that contains the plan of the building.

The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the disclosed subject matter.

### BRIEF DESCRIPTION OF THE FIGURES

FIG. 1 illustrates a system for generating vector versions of plans according to an exemplary embodiment of the present disclosure.

FIG. 2 illustrates a portion of a plan from a blueprint according to an exemplary embodiment of the present disclosure.

FIG. 3 illustrates a document analysis of a blueprint according to an exemplary embodiment of the present disclosure.

FIG. 4 illustrates a portion of a blueprint containing a plan according to an exemplary embodiment of the present disclosure.

FIG. 5 illustrates a method for generating vector versions of plans according to an exemplary embodiment of the present disclosure.

FIG. 6 illustrates a computer system according to an exemplary embodiment of the present disclosure.

### DETAILED DESCRIPTION OF EXAMPLE EMBODIMENTS

Blueprints may be received as scanned images of the original blueprint document. These scanned images are typically stored in the form of raster images (e.g., images with a fixed resolution). Such scanned images are difficult to use when attempting to quickly determine the layout of a building. For example, blueprints typically include many types of sheets depicting different aspects of the building. Floor sheets may depict details regarding the precise layout and/or positioning of individual floors of the building. Elevation sheets may depict exterior views of the building from various sides. Other sheets may depict further details, such as landscaping, parking lots, storage areas, and/or other aspects of the building. As another example, for blueprints stored as raster images, when zoomed in to view particular details, the images may become blurry and unclear.

Furthermore, it is often necessary to generate three-dimensional models of existing structures (e.g., for military, fire department, police, realty, and other uses). Existing systems require the use of LIDAR or other three-dimensional scanning technologies to scan the internal and exterior building geometry. This is cumbersome and disruptive to property owners and those performing the scans. Furthermore, these techniques cannot be performed on an as-needed basis (e.g., for real-time fire department or military responses).

Therefore, there exists a need to generate high-quality vector versions of building plans for structures. The vector versions may need to be either two-dimensional and/or three-dimensional, depending on the related use case. One solution to this problem is to use a combination of different types of machine learning models to analyze received documents to detect and generate vector versions of received blueprints (e.g., floor plans or other plans from received blueprints). In particular, a first machine learning model may be used to identify the location of a plan within a page of a received document (e.g., excluding other information on the page such as titles, architect information, page numbering). The portion of the page containing the plan may then be extracted for future analysis. In particular, a second machine learning model may analyze the plan extracted from the document to determine a type of plan that is depicted (e.g., between a structural plan, an electrical plan, an HVAC plan, and other types of plans). A third model may then receive the plan and may identify individual elements within the plan that should be included within the vector version of the plan. For example, the model may identify locations and labels for these elements indicating where the elements are within the plan and what type of elements they are. The vector version of the plan may then be generated based on the locations and labels of the individual elements (e.g., by generating and position vector versions of the individual elements). Where a three-dimensional vector version is desired, the vector version may be extruded according to the heights of the individual elements, which may also be determined by the same model that identified the individual elements (or by a different model). In certain instances, plans may span across multiple pages of a document. In such instances, a further model may be used to identify adjacent pages, which may then be combined to form a complete version of the plan.

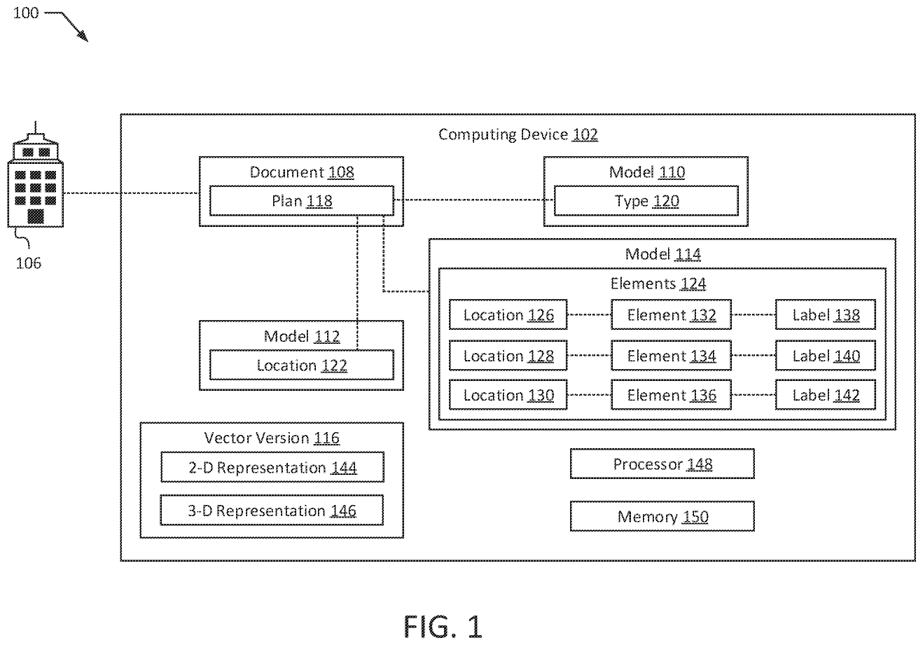

FIG. 1 illustrates a system 100 for generating vector versions of plans according to an exemplary embodiment of the present disclosure. The system 100 may be configured to receive documents 108 depicting blueprints of structures 106. The documents 108 may depict sheets or pages from one or more blueprints or building plans corresponding to a structure 106. For example, the document 108 may depict one or more floor plans, construction documents, floor sheets, elevation sheets, site plans, and the like for the structure 106. In particular, the document 108 may depict floor sheets containing one or more different types of plans for the structure 106. The computing device 102 may receive the document 108 from a database, such as a public repository of building plans and/or blueprints. Additionally or alternatively, the document 108 may be received from a scanner that is scanned a hard copy of the blueprints to generate the document 108. In certain instances, the document 108 may be received as a native document (e.g., an image, a TIFF document, a PDF document) generated by software used to prepare the blueprints (e.g., exported from the software).

Although depicted as a building in FIG. 1, in practice, the structure 106 may include any type of structure (e.g., man-made structure). For example, the building 106 may include any structure with an interior space that is at least partially enclosed. As a specific example, the structure may include single-story buildings, multi-story building, warehouse structures, infrastructure facilities, outdoor structures (e.g., pavilions, gazebos, decks, bridges, dams), or combinations thereof. As a further example, infrastructure facilities may include interior and exterior structures of dams, storm water pipes, sewer pipes, tunnels (e.g., access tunnels, tunnels for automobiles), channels, utility stations (e.g., pump stations), conduits (e.g., electrical conduits), and the like. In still further implementations, the structures may include part or other components (e.g., mechanical components, chemical components, electrical components) of other products or devices (e.g., vehicle components, aircraft components, artillery components, weapon components). Accordingly, any reference to buildings herein should be understood to apply similarly to any type of structure. Similarly, the present disclosure uses the terms “blueprint” and “plan” (and similar terms) to refer to plans for buildings and other structures. One skilled in the art will understand that, in practice, these documents may be referred to using different terminology in other instances. For example, such documents may be referred to as “site plans,” “facility plans,” or other analogous terminology. As a further example, the plans discussed herein may include one or more floor plans, elevation plans, circuit board layout diagrams, product design plans, and the like. As one specific example, the structure may include an engine of an aircraft, and the plan may include a product design plan for the engine. As another specific example, the structure may include an artillery weapon, and the plan may include a multi-view structural plan or product design plan for the artillery weapon.

The computing device 102 may be configured to use multiple models 110, 112, 114 to analyze the document 108 and generate a vector version 116 of one or more plans depicted within the document 108. For example, the computing device 102 may use three different types of machine learning model 110, 112, 114 to perform this analysis. In particular, the computing device 102 may use a first machine learning model 110 to determine a type of plan depicted within the document 108. The computing device 102 may also use a second machine learning model to determine a location of the plan 118 within the document 108. The computing device 102 may further use a third model 114 to detect individual elements of the structure 106 within the plan 118.

In particular, the model 110 may be configured to receive a copy of the document 108 and to analyze the contents of the document 108 (e.g., images depicted within the document 108) to detect a type 120 of the plan 118 depicted within the document 108. In particular, the document 108 may contain one or more images of one or more pages of a blueprint for the structure 106. The model 110 may determine a type 120 of plan depicted within at least a subset of the one or more images. The model 110 may be trained to distinguish between multiple types of plans and other plans within a blueprint. For example, different pages of a blueprint may depict different types of plans, such as a structural plan, an electrical plan, a plumbing plan, an HVAC plan, a fire suppression plan, and/or a life and safety plan. The model may be trained to distinguish between these types of plans and/or pages of the document 108 that do not contain plans (e.g., using labeled examples. In certain implementations, the model 110 may be implemented as a classifier model, such as a nearest neighbor model, a decision tree model, a logistic regression model, and the like. In additional or alternative implementations, the model 110 may be implemented as a different type of machine learning model, such as one or more of a neural network (e.g., a convolutional neural network, a recurrent neural network), a supervised learning model, an unsupervised learning model, a clustering model, a regression model, and/or a reinforcement learning model.

The model 112 may be configured to receive a copy of the document 108 and determine a location 122 of the plan 118 within the document 108. In particular, the model 112 may be configured to determine a bounding box that encompasses the plan 118 within the document 108 as the location 122 of the plan 118. In particular, the model 112 may be trained using one or more labeled examples to determine the bounding box as the location 122. For example, pages of a blueprint may typically contain additional information beyond just the plan or plan depicted (e.g., architect identifying information, building information, title information, page numbers, and the like). The model 112 may be trained to distinguish between these elements and the portions of the document 108 containing the actual plan when identifying the location 122 (e.g., the bounding box). In certain implementations, processing by the model 112 may be independent of the processing performed by the model 110. In additional or alternative implementations, the model 112 may determine the location 122 before processing is performed by the model 110. For example, the model 110 may be provided with a portion or subset of the document 108 (e.g., the portion contained within the bounding box identified by the model 112) and may determine the type 120 based on the contents of the portion of the document 108. The model 112 may be implemented as an object recognition model (e.g., a convolutional neural network). In additional or alternative implementations, the model 112 may be implemented as a different type of machine learning model, such as one or more of a neural network (e.g., a convolutional neural network, a recurrent neural network), a supervised learning model, an unsupervised learning model, a clustering model, a regression model, and/or a reinforcement learning model.

The model 114 may be configured to receive a copy of the document 108 and/or the portion of the document 108 containing the plan 118 and to identify individual elements 124 within the plan. The elements 124 may include individual elements 132, 134, 136 depicted and/or identified within the plan 118. The model 114 may additionally identify locations 126, 128, 130 (e.g., bounding boxes) for the elements 132, 134, 136. The model 114 may also identify additional information regarding the elements 132, 134, 136 (e.g., type of element, load capacity, material, power capacity), which may be stored as labels 138, 140, 142 corresponding to the individual elements 132, 134, 136. In certain implementations, the types of elements 132, 134, 136 and labels 138, 140, 142 identified by the model 114 may depend on the type 120 identified by the model 110. For example, if the type 120 is a structural plan, the model 114 may identify the elements 132, 134, 136 to include one or more of doors, load-bearing walls, non-load-bearing walls, windows, support beams, foundation structures, and the like. As another example, if the type 120 is an electrical plan, the model 114 may identify the elements 132, 134, 136 to include electrical wiring runs (e.g., locations, power ratings, install date), outlets (e.g., 120 V, 240 V), fuse boxes, light fixtures, Ethernet/coaxial cable runs, and the like. In a further example, if the type 120 is an HVAC plan, the model 114 may identify the elements 132, 134, 136 to include one or more of ductwork, intake vents, outflow vents, air conditioners, furnaces, air filters, and the like. The model 114 may be implemented as a segmentation model (e.g., a neural network trained to segment received inputs). In additional or alternative implementations, the model 114 may be implemented as a different type of machine learning model, such as one or more of a neural network (e.g., a convolutional neural network, a recurrent neural network), a supervised learning model, an unsupervised learning model, a clustering model, a regression model, and/or a reinforcement learning model. In certain implementations, the model 114 may be implemented as multiple machine learning models (e.g., separate models for different types of plans). In such instances, the computing device 102 may select the model 114 based on the type 120.

Based on the outputs from the models 110, 112, 114 (e.g., the type 120, elements 132, 134, 136, locations 126, 128, 130, and/or labels 138, 140, 142), the computing device 102 may generate the vector version 116 of the plan. The vector version 216 may include a two-dimensional representation 144 of the plan 118 (e.g., by generating vector depictions of the elements 124). In particular, the computing device 102 may generate vector representations of the elements 132, 134, 136 at their corresponding locations 126, 128, 130 within the plan 118. The shapes, sizes, and depictions of the vector representations may be generated based on the labels 138, 140, 142 and/or the depictions (e.g., corresponding shapes) of the elements 132, 134, 136 within the document 108 and the plan 118. In certain implementations, the vector version of the plan 118 may be generated based on multiple plans 118 of the same structure 106 and/or the same portions (e.g., the same floor, level, room) of the structure 106. For example, the computing device 102 may combine elements 124 extracted from multiple types of plan (e.g., a structural plan, an electrical plan, an HVAC plan) to generate the vector version 116 to depict all of the plans. As another example, a user may be able to select and switch between different types of plans. For example, a graphical user interface (GUI) used to view the vector version 116 may enable the user to toggle on and off each of the structural plan, electrical plan, and HVAC plan. In additional or alternative implementations, the vector version 116 may include a three-dimensional representation 146 of the plan 118. For example, the computing device 102 may be configured to extrude the two-dimensional representation 144 (e.g., based on the labels 138, 140, 142). As one specific example, in a structural plan, the computing device 102 may extrude the height of walls to a first standard height (e.g., 10-feet) and may extrude the height of doors to a second standard height (e.g., 8 feet). As another example, the extrusion heights for different elements 132, 134, 136 may be determined based on information contained within the plan 118 (e.g., corresponding heights indicated for various elements, standard heights for walls, doors, windows indicated on the same or a different page as the plan 118. In such implementations, the heights for the elements 132, 134, 136 may be stored as a portion of the labels 138, 140, 142. The extruded versions may be provided as a three-dimensional representation 146 of the structure 106, or a portion thereof. When displayed on a computing device (e.g., the computing device 102 or another computing device), the user may be able to navigate throughout the three-dimensional representation 146 (e.g., perform a fly-through) of the structure 106. In certain implementations, the computing device 102 may combine multiple documents (or multiple pages of the same document 108) for multiple portions of the structure 106 (e.g., multiple rooms, multiple rooms, multiple buildings, interior/exterior of a building) to generate a complete three-dimensional representation of the structure 106.

The labels 138 may include additional information beyond indicating what type of elements 132, 134, 136 have been identified in the plan 118. For example, the labels 132, 134, 136 may also indicate structural details for elements 132, 134, 136 identified in structural plans (e.g., structural materials, heights of walls/doors/windows, interior/exterior colors of walls/doors, interior/exterior trim of walls, façade features for external walls, ornamental design features, loading capacity of walls, types of insulation). The labels 132, 134, 136 may also indicate other types of metadata for the elements 132, 134, 136, such as identifying a technician or contractor that installed the elements 132, 134, 136, installation dates for the elements 132, 134, 136, maintenance or repairs performed or required, and the like. As a further example, the labels may also indicate operating parameters for elements 132, 134, 136 identified in electrical plans (e.g., wire gauges, fuse ratings, lighting wattage/lumens, number/voltage of plugs in outlets). Such additional information may be identified on the same page as the plan 118. Additionally or alternatively, the information for the labels 138, 140, 142 may be identified on another page of the document 108.

The above-discussed examples of the plan 118 and the vector version 116 focus on interior design elements and/or plans for structures 106. It should be understood that these discussions are merely exemplary. In practice, plans analyzed by the models 110, 112, 114 may include one or more external elements (e.g., exterior design features, exterior facilities, exterior landscaping features, external fixtures). In such instances, it should be understood that the vector version 116 (i.e., a two-dimensional representation 144 and/or a three-dimensional representation 146) may include these external elements and the model 114 may be trained to identify external elements.

The computing device 102 also includes a processor 148 and a memory 150. The processor 148 and the memory 150 may implement one or more aspects of the computing device 102. For example, the memory 150 may store instructions which, when executed by the processor 148, may cause the processor 148 to perform one or more operational features of the computing device 102 (e.g., implement one or more of the models 110, 112, 114). The processor 148 may be implemented as one or more central processing units (CPUs), field programmable gate arrays (FPGAs), and/or graphics processing units (GPUs) configured to execute instructions stored on the memory 150. Additionally, the computing device 102 may be configured to communicate (e.g., to receive the document 108 and/or to transmit the vector version 116) using a network. For example, the computing device 102 may communicate with the network using one or more wired network interfaces (e.g., Ethernet interfaces) and/or wireless network interfaces (e.g., Wi-Fi®, Bluetooth®, and/or cellular data interfaces). In certain instances, the network may be implemented as a local network (e.g., a local area network), a virtual private network, L1 and/or a global network (e.g., the Internet).

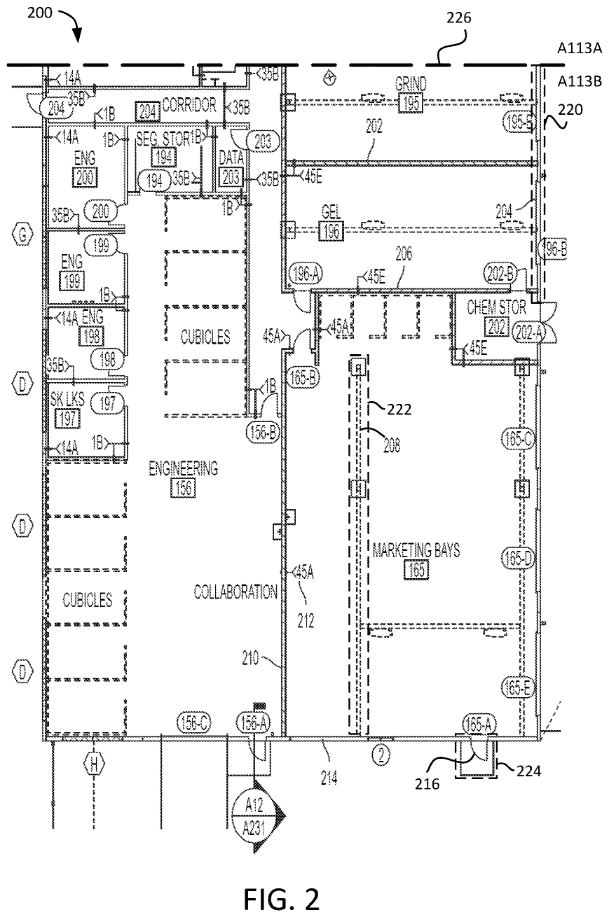

FIG. 2 illustrates a portion of a plan 200 from a blueprint according to an exemplary embodiment of the present disclosure. The blueprint 200 may be an exemplary implementation of a document 108 received by the computing device 102. The plan 200 includes various elements of a building structure, a portion of which are identified using reference numerals for discussion below. The plan 200 as depicted may be a part of a floor of a building. The plan 200 includes depictions of exterior walls 204, 214 and interior walls 202, 206, 210 (only a subset of which are numbered for clarity). The interior walls 202, 206, 210 include two different types of walls: interior partition walls 202, 206 and interior load-bearing walls 210. The plan 200 also includes a depiction of a foundation structure 208, along with structural ties 212 connecting other parts of the building (e.g., the interior load-bearing wall 210) to the foundation structure 212.

In certain implementations, not all of the depicted features may be necessary to properly determine an interior layout of the building. For example, the foundation structure 208 and the structural ties 212 may not be necessary to accurately determine the interior layout of the floor. Accordingly, in certain implementations, the model 114 may be trained to not identify elements 132, 134, 136 based on foundation structures 208 and/or structural ties 212. In additional or alternative implementations, the computing device 102 may be configured to generate a separate layer or model for the foundation structure 208 and structural ties 212 that a user can toggle on and off in the vector version 116.

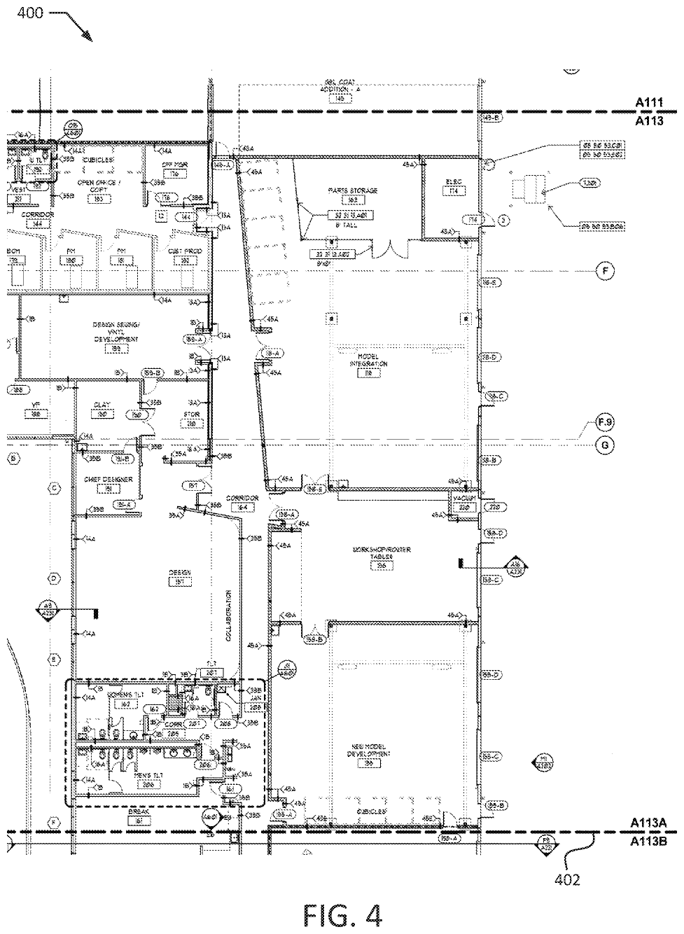

The plan 200 further includes a dividing line 226 referencing an additional document (e.g., another page of the same blueprint) or portion of a corresponding plan for an adjacent part of the building (discussed in greater detail in connection with FIG. 4. The plan 200 also includes bounding boxes 218, 220, 222, 224 around corresponding elements 202, 204, 208, 216, discussed in greater detail below.

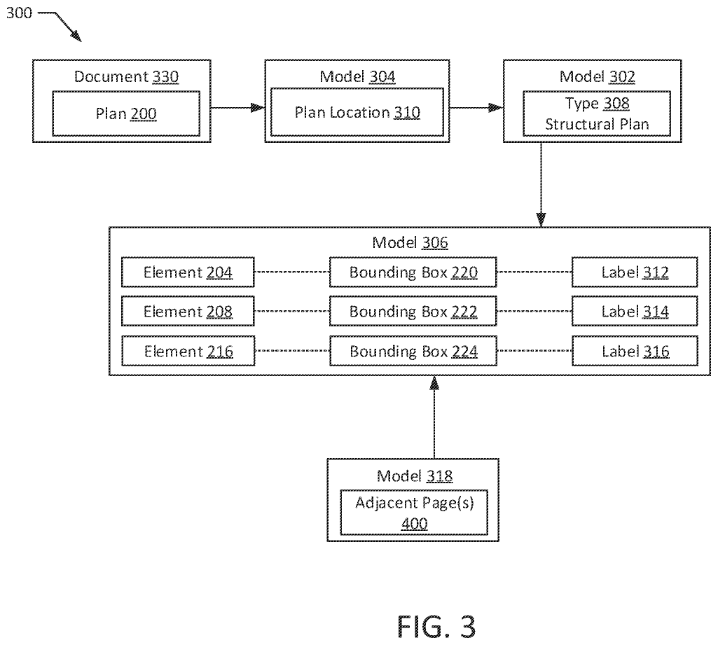

FIG. 3 illustrates a document analysis 300 of a blueprint according to an exemplary embodiment of the present disclosure. The document analysis 300 may be an example implementation of the analysis performed by the computing device 102. For example, the model 302 may be an exemplary implementation of the model 110, the model 304 may be an exemplary implementation of the model 112, and the model 306 may be an exemplary implementation of the model 114. The computing device 102 may receive a document 330 containing the plan 200 (e.g., as a scanned copy of a blueprint containing the plan 200). The document 330 may contain additional pages, which are not depicted (e.g., containing different plans for the same or different structures). Furthermore, the page of the document 330 may be larger than the plan 200 as depicted, and may contain additional information (e.g., titles, architect information, page number information) that needs to be separated from the plan 200 for further analysis.

Accordingly, the model 304 determines a bounding box surrounding the plan 200 within the document 330 (e.g., the portion depicted in FIG. 2) and excludes the additional information contained in other portions of the document. The bounding box may be determined as the location 310 of the plan 200, and the plan 200 contained within the bounding box may be extracted for further analysis by the models 302, 306.

The model 302 may receive the plan 200 and/or the document 330 and may analyze the plan 200 and/or document 330 to determine a type 308 of plan depicted in the document image 200. For example, the model 302 may be trained to distinguish between one or more of a structural plan, an electrical plan, a plumbing plan, an HVAC plan, a life and safety plan, and/or a fire suppression plan. The model 302 may determine (e.g., based on the contents of the plan 200) the type 308 of the plan 200 is a structural plan. In certain implementations, the model 302 may determine more than one type 308 for a single plan 200. For example, certain plans may depict multiple different structural elements (e.g., may combine a fire suppression plan and a plumbing plan). In such instances, the model 302 may assign multiple types to the plan (e.g., a fire suppression plan type and a plumbing plan type). Depending on the type 308, the document analysis 300 may proceed for the plan 200. For example, additional processing (e.g., by the model 306) may continue based on the types of elements desired in the vector version 116. As one specific example, the vector version 116 may be generated to contain structural plans, electrical plans, and HVAC plans (e.g., according to a predetermined preference, according to a user preference). Because the plan 200 has a type 308 of structural plan, processing may continue with the model 306.

The model 306 may receive the portion of the document 330 containing the plan 200 (e.g., from the model 304) and may analyze the plan 200 to identify individual elements 204, 208, 210 within the plan 200. As explained further above, the model 306 may identify one or more predetermined types of elements based on the type 308. For example, because the plan 200 depicts a structural plan, the model 306 may identify doors, load-bearing walls, non-load-bearing walls, support beams, support pillars, windows, foundation structures, and the like. In particular, the model 306 may identify bounding boxes 220, 222, 224 around the elements 204, 208, 216 within the plan 200. In particular, the model 306 may identify a bounding box 220 that surrounds the exterior wall 204, a bounding box 222 that surrounds the foundation structure 208, and a bounding box 224 that surrounds the door 216. Based on the type of the elements 204, 208, 216, the model 306 may also assign corresponding labels 312, 314, 316 to the elements 204, 208, 216. For example, the model 306 may assign a label 312 of “exterior wall” and/or “load-bearing wall” to the exterior wall 204 (e.g., by assigning the label 312 to the bounding box 220 corresponding to the location of the exterior wall 204). Similarly, the model 306 may assign a label 314 of “foundation structure” to the bounding box 222 indicating the location of the foundation structure 208 and may assign a label of “door” or “exterior door” to the bounding box 224 indicating the location of the door 216. As explained further above, the labels 312, 314, 316 may contain additional information beyond identifying the type of elements 204. For example, the label 312 may indicate materials for the wall 204, a height of the wall 204, interior/exterior colors of the wall 204, and/or a loading capacity of the wall 204. Similarly, the label 314 may indicate materials for the foundation structure 208, an installation date for the foundation structure 208, and the like. Additionally, the label 316 may indicate materials for the door 216 (e.g., wood, metal, composite), a height of the door 216, interior/exterior colors of the door 216, an impact resistance for the door 216, whether the door has a lock, whether the door is an emergency exit, and the like. This information may be determined from other pages of the document 330, which may indicate heights, materials, and other information, for the elements depicted in plans of the structure.

In certain instances, the computing device may include an additional model 318 configured to identify adjacent pages 400 depicting adjacent portions of a plan that should be merged with the plan depicted in the document image 200. For example, the model 318 may be configured to look for joining lines, common design features (e.g., common geometery) and/or common reference numbers to identify the adjacent pages 400. FIG. 4 illustrates a portion of an adjacent page 400 for the document image 200. In particular, the model 318 may identify the common joining lines 226, 402. For example, the model 318 may identify the joining lines 226, 402 and the common reference numbers A113A and A113B next to each of the joining lines 226, 402. Based on this, the model 318 may determine that the plan 200 is adjacent to the plan depicted in page 400. To join the adjacent pages, a computing device 102 may process the document images for the document 330 and the adjacent page 400 to extract the portions of each that contain the plans (e.g., using the model 304 and may merge these portions. Adjacent pages may be joined either before or after subsequent processing (e.g., by the models 302, 306). If the adjacent pages are joined after analysis by the model 306, locations of the bounding boxes 220, 222, 224 may be adjusted based on a common coordinate system between the merged adjacent pages. In practice, more than two adjacent pages may need to be merged. For example, the model 318 may be configured to identify 5, 10, 25, or more pages, which may then be merged as explained above.

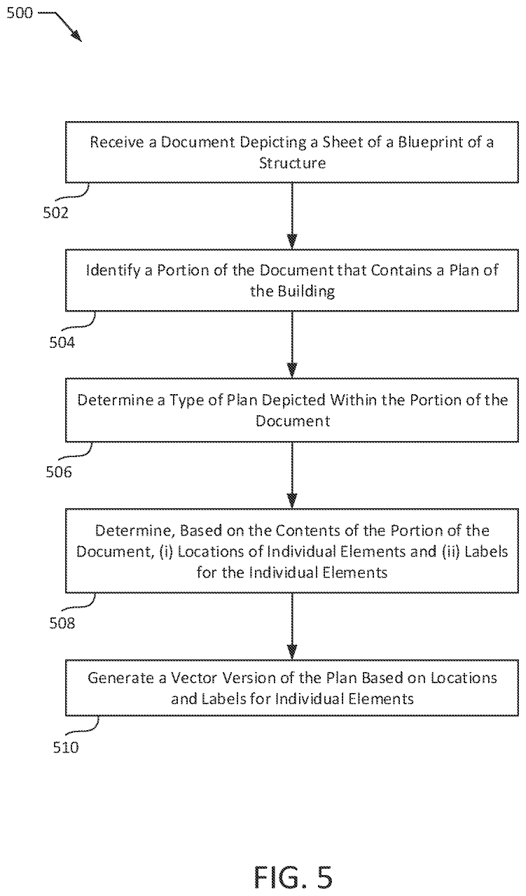

FIG. 5 illustrates a method 500 for generating vector versions of plans according to an exemplary embodiment of the present disclosure. The method 500 may be implemented on a computer system, such as the system 100. For example, the method 500 may be implemented by the computing device 102. The method 500 may also be implemented by a set of instructions stored on a computer readable medium that, when executed by a processor, cause the computer system to perform the method 500. For example, all or part of the method 400 may be implemented by the processor 148 and the memory 150. Although the examples below are described with reference to the flowchart illustrated in FIG. 5, many other methods of performing the acts associated with FIG. 5 may be used. For example, the order of some of the blocks may be changed, certain blocks may be combined with other blocks, one or more of the blocks may be repeated, and some of the blocks described may be optional.

The method 500 may begin with receiving a document depicting a sheet of a blueprint of the structure (block 502). For example, the computing device 102 may receive a document 108 depicting a sheet of a blueprint of a structure 106. In particular, one or more sheets of the blueprint may depict different types of plans 118 for the structure 106. As explained above, the structure 106 may include a building, vehicle, infrastructure, or other structures. The document 108 may be received from another computing device and/or a database storing blueprints for various structures. In particular, the document may be received by the computing device 102 and response to a request received from a user to generate a vector version 116 of plans for the structure 106.

A portion of the document that contains a plan of the building may be identified (block 504). For example, the computing device 102 may identify a location 122 for a portion of the document 108 that contains a plan 118. In particular, the computing device 102 may analyze individual pages of the document 108 and identify portions of those individual pages that contain plans. For example, as explained above, the location 122 may be determined as a bounding box around plans contained on various pages within the document 108. The portion of the document 108 containing the plan 118 may then be extracted for future analysis.

A type of plan depicted within the portion of the document may be determined (block 506). In particular, the computing device 102 may determine a type 120, 308 of the plan 118. For example, the plan 118 may depict an electrical plan for the structure 106. The model 110 may analyze the contents of the plan 118 (e.g., by analyzing the portion of the document 108 containing the plan 118 received from the model 112) and determine, based on the contents, that the plan 118 has a type 120 of “electrical plan.”

Based on the contents of the portion of the document, locations of individual elements and labels for the individual elements may be determined (block 508). For example, the computing device 102 may determine locations 126, 128, 130 and labels 138, 140, 142 for individual elements 132, 134, 136 depicted within the plan 118. The elements 132, 134, 136 may be identified based on the type 120 of the plan 118. In particular, because the type 120 indicates that the plan 118 is an electrical plan, the model 114 may identify locations 126, 128, 130 and labels 138, 140, 142 for identified wiring runs and ratings, outlet locations, light locations, Ethernet/coaxial cable runs, fuse boxes, and the like within the electrical plan. As explained further above, the labels 138, 140, 142 may contain additional information regarding the elements 132, 134, 136, such as operating ratings, installation dates, wire gauges, light wattages, and the like.

A vector version of the plan may be generated based on the locations and labels for the individual elements (block 510). For example, the computing device 102 may generate a vector version 116 of the plan 118 based on the locations 126, 128, 130 in the labels 138, 140, 142. As explained above, the vector version 116 may include one or more of a two-dimensional representation 144 and a three-dimensional representation 146. Where a three-dimensional representation 146 is desired, the computing device 102 may be configured to extrude two-dimensional representations of the elements 132, 134, 136. In certain implementations, generating the vector version 116 may include generating a vector version of the individual elements 132, 134, 136. The vector version of the elements may be generated based on the label 138, 140, 142 and/or may be generated by converting the scalar representations of the elements 132, 134, 136 within the document 108 into a corresponding vector version of the elements 132, 134, 136. The vector version may then be scaled based on the location 126, 128, 130 associated with the element 132, 134, 136 (e.g., based on a size of a bounding box surrounding the elements 132, 134, 136. The vector version of the elements may then be placed within the vector version 116 of the plan 118 based on the location 126, 128, 130 associated with the element (e.g., relative to other elements within the plan 118).

Accordingly, the method 500 enables the automated generation of vector versions of plans. In particular, the computing device is able to utilize multiple machine learning models to sift through the many pages and many different types of plans contained within typical blueprints for common structures in order to identify the plans that can be used to generate the desired vector version. Furthermore, by dividing the analysis across three different machine learning models, the computing device 102 is able to increase the accuracy for subsequent processing. In particular, extracting the plan from the document initially may increase the accuracy of the identified type and/or elements within the plan. Furthermore, where the type is determined before the elements, providing this information to the model that identifies the elements (or using the type to select the model that identifies the elements) may further increase the accuracy of the identified elements by limiting which types of elements the model is configured to identify. Furthermore, because the computing device is able to parse and integrate multiple types of plans, the resulting vector versions of received plans may be able to selectively integrate multiple types of plans. Thus, the vector versions may be more complete, versatile, and accurate than those produced using other techniques. Furthermore, by utilizing multiple machine learning models, the computing device may be easily expandable to process new types of plans (e.g., by adding new models that identify elements in different types of plans, by updating the model that identifies types for received plans).

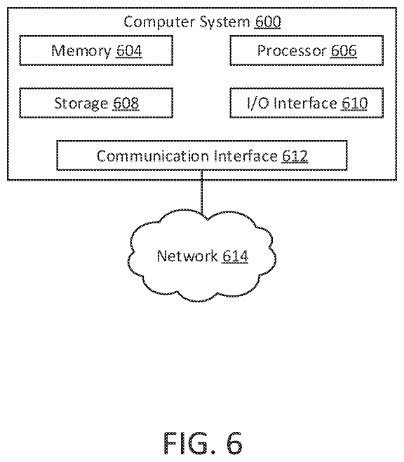

FIG. 6 illustrates an example computer system 600 that may be utilized to implement one or more of the devices and/or components discussed herein, such as the computing device 102. In particular embodiments, one or more computer systems 600 perform one or more steps of one or more methods described or illustrated herein. In particular embodiments, one or more computer systems 600 provide the functionalities described or illustrated herein. In particular embodiments, software running on one or more computer systems 600 performs one or more steps of one or more methods described or illustrated herein or provides the functionalities described or illustrated herein. Particular embodiments include one or more portions of one or more computer systems 600. Herein, a reference to a computer system may encompass a computing device, and vice versa, where appropriate. Moreover, a reference to a computer system may encompass one or more computer systems, where appropriate.

This disclosure contemplates any suitable number of computer systems 600. This disclosure contemplates the computer system 600 taking any suitable physical form. As example and not by way of limitation, the computer system 600 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, the computer system 600 may include one or more computer systems 600; be unitary or distributed; span multiple locations; span multiple machines; span multiple data centers; or reside in a cloud, which may include one or more cloud components in one or more networks. Where appropriate, one or more computer systems 600 may perform without substantial spatial or temporal limitation one or more steps of one or more methods described or illustrated herein. As an example and not by way of limitation, one or more computer systems 600 may perform in real time or in batch mode one or more steps of one or more methods described or illustrated herein. One or more computer systems 600 may perform at different times or at different locations one or more steps of one or more methods described or illustrated herein, where appropriate.

In particular embodiments, computer system 600 includes a processor 606, memory 604, storage 608, an input/output (I/O) interface 610, and a communication interface 612. Although this disclosure describes and illustrates a particular computer system having a particular number of particular components in a particular arrangement, this disclosure contemplates any suitable computer system having any suitable number of any suitable components in any suitable arrangement.

In particular embodiments, the processor 606 includes hardware for executing instructions, such as those making up a computer program. As an example and not by way of limitation, to execute instructions, the processor 606 may retrieve (or fetch) the instructions from an internal register, an internal cache, memory 604, or storage 608; decode and execute the instructions; and then write one or more results to an internal register, internal cache, memory 604, or storage 608. In particular embodiments, the processor 606 may include one or more internal caches for data, instructions, or addresses. This disclosure contemplates the processor 606 including any suitable number of any suitable internal caches, where appropriate. As an example and not by way of limitation, the processor 606 may include one or more instruction caches, one or more data caches, and one or more translation lookaside buffers (TLBs). Instructions in the instruction caches may be copies of instructions in memory 604 or storage 608, and the instruction caches may speed up retrieval of those instructions by the processor 606. Data in the data caches may be copies of data in memory 604 or storage 608 that are to be operated on by computer instructions; the results of previous instructions executed by the processor 606 that are accessible to subsequent instructions or for writing to memory 604 or storage 608; or any other suitable data. The data caches may speed up read or write operations by the processor 606. The TLBs may speed up virtual-address translation for the processor 606. In particular embodiments, processor 606 may include one or more internal registers for data, instructions, or addresses. This disclosure contemplates the processor 606 including any suitable number of any suitable internal registers, where appropriate. Where appropriate, the processor 606 may include one or more arithmetic logic units (ALUs), be a multi-core processor, or include one or more processors 606. Although this disclosure describes and illustrates a particular processor, this disclosure contemplates any suitable processor.

In particular embodiments, the memory 604 includes main memory for storing instructions for the processor 606 to execute or data for processor 606 to operate on. As an example, and not by way of limitation, computer system 600 may load instructions from storage 608 or another source (such as another computer system 600) to the memory 604. The processor 606 may then load the instructions from the memory 604 to an internal register or internal cache. To execute the instructions, the processor 606 may retrieve the instructions from the internal register or internal cache and decode them. During or after execution of the instructions, the processor 606 may write one or more results (which may be intermediate or final results) to the internal register or internal cache. The processor 606 may then write one or more of those results to the memory 604. In particular embodiments, the processor 606 executes only instructions in one or more internal registers or internal caches or in memory 604 (as opposed to storage 608 or elsewhere) and operates only on data in one or more internal registers or internal caches or in memory 604 (as opposed to storage 608 or elsewhere). One or more memory buses (which may each include an address bus and a data bus) may couple the processor 606 to the memory 604. The bus may include one or more memory buses, as described in further detail below. In particular embodiments, one or more memory management units (MMUs) reside between the processor 606 and memory 604 and facilitate accesses to the memory 604 requested by the processor 606. In particular embodiments, the memory 604 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 604 may include one or more memories 604, where appropriate. Although this disclosure describes and illustrates particular memory implementations, this disclosure contemplates any suitable memory implementation.

In particular embodiments, the storage 608 includes mass storage for data or instructions. As an example and not by way of limitation, the storage 608 may include a hard disk drive (HDD), a floppy disk drive, flash memory, an optical disc, a magneto-optical disc, magnetic tape, or a Universal Serial Bus (USB) drive or a combination of two or more of these. The storage 608 may include removable or non-removable (or fixed) media, where appropriate. The storage 608 may be internal or external to computer system 600, where appropriate. In particular embodiments, the storage 608 is non-volatile, solid-state memory. In particular embodiments, the storage 608 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 608 taking any suitable physical form. The storage 608 may include one or more storage control units facilitating communication between processor 606 and storage 608, where appropriate. Where appropriate, the storage 608 may include one or more storages 608. Although this disclosure describes and illustrates particular storage, this disclosure contemplates any suitable storage.

In particular embodiments, the I/O Interface 610 includes hardware, software, or both, providing one or more interfaces for communication between computer system 600 and one or more I/O devices. The computer system 600 may include one or more of these I/O devices, where appropriate. One or more of these I/O devices may enable communication between a person (i.e., a user) and computer system 600. As an example and not by way of limitation, an I/O device may include a keyboard, keypad, microphone, monitor, screen, display panel, mouse, printer, scanner, speaker, still camera, stylus, tablet, touch screen, trackball, video camera, another suitable I/O device or a combination of two or more of these. An I/O device may include one or more sensors. Where appropriate, the I/O Interface 610 may include one or more device or software drivers enabling processor 606 to drive one or more of these I/O devices. The I/O interface 610 may include one or more I/O interfaces 610, where appropriate. Although this disclosure describes and illustrates a particular I/O interface, this disclosure contemplates any suitable I/O interface or combination of I/O interfaces.

In particular embodiments, communication interface 612 includes hardware, software, or both providing one or more interfaces for communication (such as, for example, packet-based communication) between computer system 600 and one or more other computer systems 600 or one or more networks 614. As an example and not by way of limitation, communication interface 612 may include a network interface controller (NIC) or network adapter for communicating with an Ethernet or any other wire-based network or a wireless NIC (WNIC) or wireless adapter for communicating with a wireless network, such as a Wi-Fi network. This disclosure contemplates any suitable network 614 and any suitable communication interface 612 for the network 614. As an example and not by way of limitation, the network 614 may include one or more of an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 600 may communicate with a wireless PAN (WPAN) (such as, for example, a Bluetooth® WPAN), a WI-FI network, a WI-MAX network, a cellular telephone network (such as, for example, a Global System for Mobile Communications (GSM) network), or any other suitable wireless network or a combination of two or more of these. Computer system 600 may include any suitable communication interface 612 for any of these networks, where appropriate. Communication interface 612 may include one or more communication interfaces 612, where appropriate. Although this disclosure describes and illustrates a particular communication interface implementations, this disclosure contemplates any suitable communication interface implementation.

The computer system 602 may also include a bus. The bus may include hardware, software, or both and may communicatively couple the components of the computer system 600 to each other. As an example and not by way of limitation, the bus may include an Accelerated Graphics Port (AGP) or any other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-PIN-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these buses. The bus may include one or more buses, where appropriate. Although this disclosure describes and illustrates a particular bus, this disclosure contemplates any suitable bus or interconnect.

Herein, a computer-readable non-transitory storage medium or media may include one or more semiconductor-based or other types of integrated circuits (ICs) (e.g., field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

1. A method comprising:
receiving a document depicting a sheet of a blueprint of a structure;
identifying, with a first machine learning model, a portion of the document that contains a plan of the structure;
determining, with a second machine learning model, a type for the plan depicted within the portion of the document;
determining, with a third machine learning model and based on the contents of the portion of the document, (i) locations of individual elements within the plan and (ii) labels for the individual elements within the plan; and
generating a vector version of the floor plan based on the locations and labels for individual elements within the floor plan.

2. The method of claim 1, wherein the first machine learning model identifies a bounding box that surrounds the portion of the document that contains the plan of the building.

3. The method of claim 2, wherein the portion of the document is extracted from the document and provided to the second machine learning model.

4. The method of claim 1, wherein the type is selected from among a predefined plurality of types of plans.

5. The method of claim 4, wherein the plurality of types of floor plans includes at least one of a structural plan, an electrical plan, a plumbing plan, an HVAC plan, a life and safety plan, and/or a fire suppression plan.

6. The method of claim 1, wherein locations and labels for individual elements are determined responsive to determining that the type for the floor plan is a structural plan.

7. The method of claim 1, wherein generating the vector version of the floor plan includes, for each element of at least a subset of the individual elements:
generating a vector version of the element based on a label corresponding to the element and contents of the floor plan at a location associated with the element;
scaling the vector version of the element based on the location associated with the element; and
placing the vector version of the element within the vector version of the floor plan based on the location associated with the element.

8. The method of claim 1, wherein receiving the document includes receiving multiple documents depicting multiple sheets of the blueprint of the structure, and wherein the method is repeated at least in part for multiple floor plans depicted in each of at least a subset of the multiple documents.

9. The method of claim 8, wherein the method further comprises combining multiple vector versions of the multiple floor plans to generate a three-dimensional representation of the structure.

10. The method of claim 9, wherein the method further comprises, prior to determining the locations and labels for individual elements:
identifying a common match line within two or more of the multiple documents; and
combining the two or more of the multiple documents to generate a single floor plan, wherein the single floor plan is provided to the third machine learning model for use in determining the locations and labels for individual elements.

11. The method of claim 1, wherein at least one of (i) the first model is an object recognition model, (ii) the second model is a classifier model, and/or (iii) the third model is a segmentation model.

12. The method of claim 1, wherein the structure includes at least one of, a building, a vehicle, an infrastructure component, a ship, a spacecraft, an aircraft, a tank, and/or an appliance.

13. The method of claim 1, wherein the structure includes components for one or more of a vehicle, a ship, a spacecraft, an aircraft, a tank, an artillery, and/or a weapon.

14. The method of claim 1, wherein the floor plan includes an exterior portion surrounding the structure and the vector version of the floor plan includes a representation of the exterior portion.

15. The method of claim 1, wherein the vector version of the floor plan is at least one of (i) a two-dimensional vector representation of the floor plan and (ii) a three-dimensional vector representation of the floor plan.

16. The method of claim 1, wherein the vector version of the floor plan allows a user to navigate a three-dimensional representation of the floor plan.

17. A system comprising:
a processor; and
a memory storing instructions which, when executed by the processor, cause the processor to:
receive a document depicting a sheet of a blueprint of a structure;
identify, with a first machine learning model, a portion of the document that contains a plan of the structure;
determine, with a second machine learning model, a type for the plan depicted within the portion of the document;
determine, with a third machine learning model and based on the contents of the portion of the document, (i) locations of individual elements within the plan and (ii) labels for the individual elements within the floor plan; and
generate a vector version of the floor plan based on the locations and labels for individual elements within the floor plan.

18. The system of claim 17, wherein the memory contains additional instructions which, when executed by the processor while generating the vector version of the floor plan, causes the processor to, for each element of at least a subset of the individual elements:
generate a vector version of the element based on a label corresponding to the element and contents of the floor plan at a location associated with the element;
scale the vector version of the element based on the location associated with the element; and
place the vector version of the element within the vector version of the floor plan based on the location associated with the element.

19. The system of claim 17, wherein at least one of (i) the first model is an object recognition model, (ii) the second model is a classifier model, and/or (iii) the third model is a segmentation model.

20. The system of claim 17, wherein the first machine learning model identifies a bounding box that surrounds the portion of the document that contains the plan of the building.
